(19) United States
(12) Patent Application Publication
(10) Pub. No.: US 2026/0162713 A1
(43) Pub. Date: Jun. 11, 2026

(54) MEMORY CIRCUIT AND INFORMATION PROCESSING APPARATUS

(71) Applicant: Fujitsu Limited, Kawasaki-shi (JP)

(72) Inventor: Kenji GOTO, Kawasaki (JP)

(73) Assignee: Fujitsu Limited, Kawasaki-shi (JP)

(21) Appl. No.: 19/371,750

(22) Filed: Oct. 28, 2025

(30) Foreign Application Priority Data
Dec. 11, 2024 (JP) 2024-216227

(51) Int. Cl. G11C 11/418; G11C 11/419; H03K 19/017

(52) U.S. Cl. CPC G11C 11/418; G11C 11/419; H03K 19/01721; G11C 2207/2281

(57) ABSTRACT

A memory circuit including a word line driver configured to set a potential of a word line signal input to a selected memory cell to a second value lower than a first value by a certain amount until a stable operation of the memory cell is ensured, a timing adjustment circuit configured to determine a time at which the potential of the word line signal is set to the second value, and a pull-up circuit configured to boost the potential of the word line signal from the second value to the first value according to the determined time.

### CROSS-REFERENCE TO RELATED APPLICATION

This application is based upon and claims the benefit of priority of the prior Japanese Patent application No. 2024-216227, filed on Dec. 11, 2024, the entire contents of which are incorporated herein by reference.

### FIELD

The present embodiment relates to a memory circuit and an information processing apparatus.

### BACKGROUND

With miniaturization in the semiconductor technology, manufacturing variations become larger, leading to increased variations in transistor characteristics, wiring resistance, and capacitance. In addition, in recent years, advances in industrial use of artificial intelligence (AI) and big data have led to the need for computing power to process large amounts of data, and there is a strong demand for lower operating voltages to reduce the power consumption of large scale integrated (LSI) circuits. When the variation is large and the voltage is low, the stability (static noise margin (SNM)) of the memory cell decreases during reading a static random access memory (SRAM), making it impossible to retain data in the memory cell.

FIG. 1 is a diagram illustrating a circuit 6 including a memory cell (MC) 61 and a word line (WL) driver 62 in a first conventional example. FIG. 2 is a diagram illustrating a WL signal and a node operation waveform in the MC 61 in the circuit 6 illustrated in FIG. 1.

The MC 61 includes six transistors (PU0, PU1, PG0, PG1, PD0, and PD1), and access to MC data is implemented by a WL signal. Here, it is assumed that a C node is at a low potential (LO) and a CX node is at a high potential (HI) in an initial state of a read operation. At the beginning of the read operation, bit lines (BL and BLB) are precharged to HI by a precharge circuit (not illustrated).

Next, as indicated by reference sign A1 in FIG. 2, the MC 61 is accessed by setting the WL signal to HI. Since BL is at HI and C is at LO, a current I_{CELL} flows from BL through PG0 and PD0. In a case where the transistors of the MC 61 after being manufactured vary in performance and the driving force ratio between PD0 and PG0 (PD driving force/PG driving force) becomes small, the potential rise of C increases as indicated by reference sign A2 in FIG. 2. As a result, PD1 to which C is connected reacts, causing CX to start to drop, and eventually C and CX invert, leading to data destruction.

Various read assist circuits have been proposed to ensure a stable operation. The most common method is a word line under drive (WLUD) method, which improves the stability of the MC by lowering the WL level during access to the memory cell to be lower than the power supply voltage.

FIG. 3 is a diagram illustrating a circuit 6a in a second conventional example. FIG. 4 is a diagram illustrating a WL signal and a node operation waveform in the MC 61 in the circuit 6a illustrated in FIG. 3.

The circuit 6a illustrated in FIG. 3 includes a step-down circuit 63 in addition to the MC 61 and the WL driver 62 in the circuit 6 illustrated in FIG. 1.

The basic operation is the same as that in the first conventional example illustrated in FIG. 1 with no assist. It is assumed that the C node is at a low potential (LO) and the CX node is at a high potential (HI) in an initial state of a read operation. At the beginning of the read operation, the bit lines (BL and BLB) are precharged to HI by a precharge circuit (not illustrated).

As indicated by reference sign B1 in FIG. 4, the MC 61 is accessed by setting the WL signal to HI. The potential of the WL signal during access rises only to VDD-α, which is lower than the power supply voltage VDD, by the step-down circuit added as an assist circuit. Since the WL signal does not rise to VDD, the gate-source potential V_{GS} of PG0 becomes smaller, and the driving force of PG0 decreases. Therefore, the driving force ratio between PD0 and PG0 becomes large, suppressing the rise of C (solid line B2 in FIG. 4). As a problem of this method, since the WL signal is not raised to VDD, the V_{GS} of PG0 is small, and accordingly, I_{CELL} becomes small, reducing the read speed.

Therefore, a circuit that improves the reduced read speed by raising the WL signal to VDD after a certain period of time has been proposed.

FIG. 5 is a diagram illustrating a circuit 6b in a third conventional example. FIG. 6 is a diagram illustrating a WL signal and a node operation waveform in the MC 61 in the circuit 6b illustrated in FIG. 5.

As illustrated in FIG. 5, the circuit 6b includes a plurality of MCs 61 (MC[0], . . . , MC[n−1], and MC[n]), a WL driver 62a, a pull-down circuit 63a, and a pull-down circuit control signal driver 64. The WL driver 62a includes a plurality of inverters (INV[0], . . . , INV[n−1], and INV[n]). The pull-down circuit 63a includes a plurality of transistors (P[0], . . . . , P[n−1], and P[n]). n is a natural number.

The pull-down circuit 63a is connected to the WL so as not to raise the WL signal to VDD.

In FIG. 6, the WL driver INV[n] controlled by a word line selection signal /WL[n], the WL signal WL[n], the pull-down circuit P1 [n], and the memory cell MC[n] will be described.

The WL[n] potential is raised by the WL driver 62a as indicated by reference sign D1 in FIG. 6, and the potential of the control signal/WUEN of the pull-down circuit 63a is lowered before the timing (T1) when the access to MC[n] starts as indicated by reference sign D2. The pull-down circuit 63a keeps the WL signal at VDD-α.

At timing (T2) after the stability of MC[n] is ensured, the WL signal rises to VDD by raising the potential of /WUEN and turning OFF the pull-down circuit as indicated by reference sign D3. Then, as indicated by reference sign D4, as the WL signal rises to VDD, the driving force of PG0 of MC[n] rises, and accordingly, I_{CELL} becomes larger, shortening the driving force decrease period, and improving the read speed.

For example, related arts are disclosed in Japanese Laid-open Patent Publication No. 2009-070474.

### SUMMARY

According to an aspect of embodiment(s), a memory circuit including a word line driver configured to set a potential of a word line signal input to a selected memory cell to a second value lower than a first value by a certain amount until a stable operation of the memory cell is ensured, a timing adjustment circuit configured to determine a time at which the potential of the word line signal is set to the second value, and a pull-up circuit configured to boost the potential of the word line signal from the second value to the first value according to the determined time.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a circuit including an MC and a WL driver in a first conventional example;

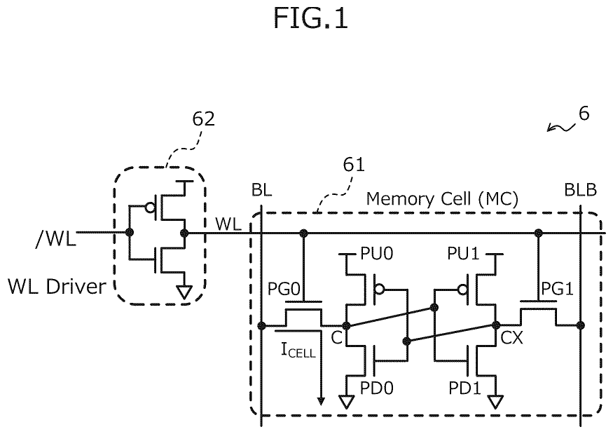

FIG. 2 is a diagram illustrating a WL signal and a node operation waveform in the MC in the circuit illustrated in FIG. 1;

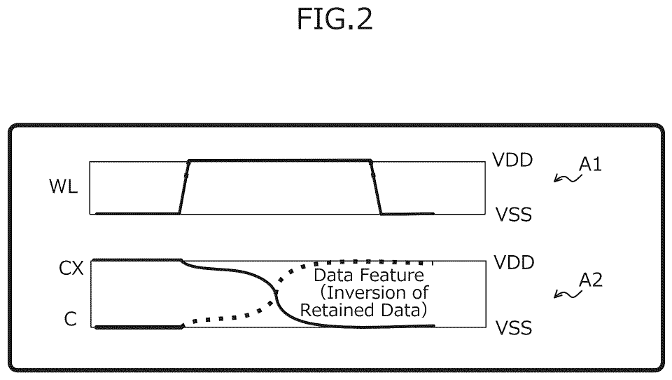

FIG. 3 is a diagram illustrating a circuit in a second conventional example;

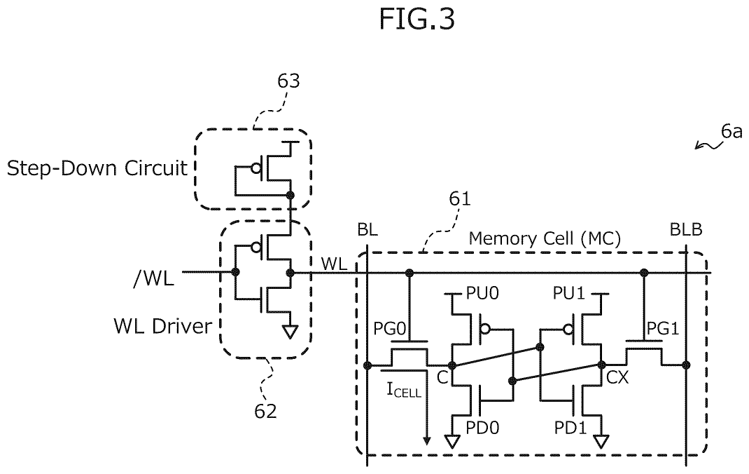

FIG. 4 is a diagram illustrating a WL signal and a node operation waveform in an MC in the circuit illustrated in FIG. 3;

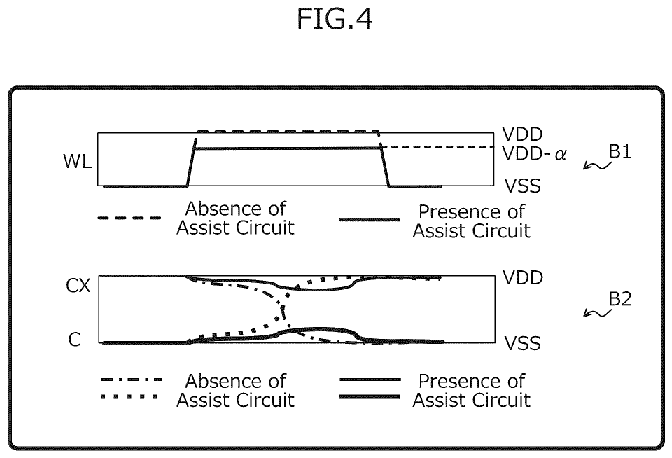

FIG. 5 is a diagram illustrating a circuit in a third conventional example;

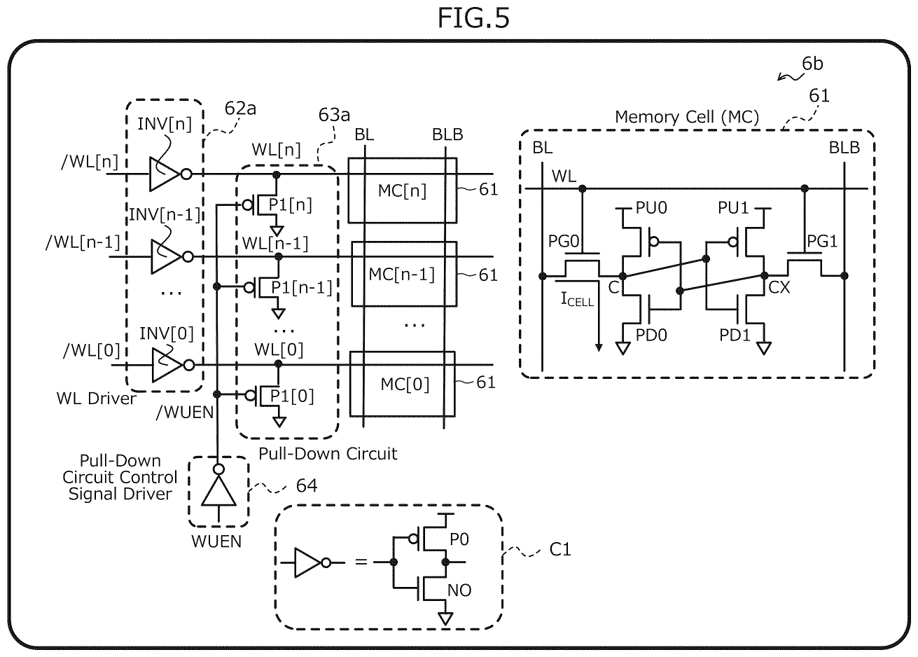

FIG. 6 is a diagram illustrating a WL signal and a node operation waveform in an MC in the circuit illustrated in FIG. 5;

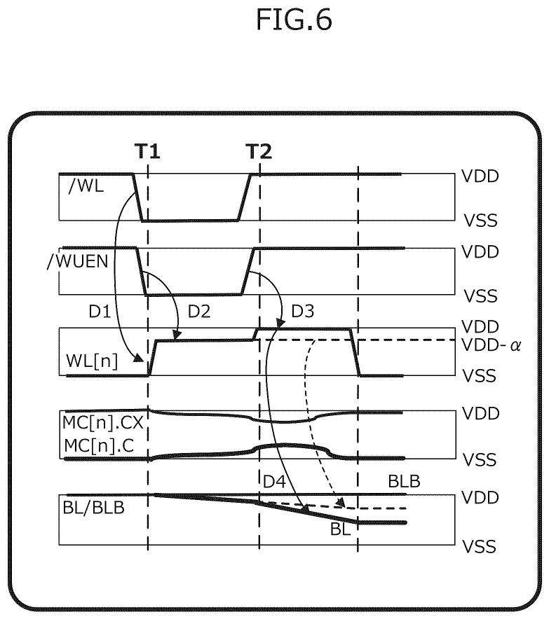

FIG. 7 is a diagram illustrating a memory circuit according to an embodiment;

FIG. 8 is a diagram illustrating a node operation waveform in the memory circuit illustrated in FIG. 7;

FIG. 9 is a diagram illustrating details of the memory circuit illustrated in FIG. 7;

FIG. 10 is a diagram illustrating a node operation waveform in the memory circuit illustrated in FIG. 8;

FIG. 11 is a diagram illustrating a memory circuit according to a first modification;

FIG. 12 is a diagram illustrating a node operation waveform in the memory circuit illustrated in FIG. 11;

FIG. 13 is a diagram illustrating a memory circuit according to a second modification;

FIG. 14 is a diagram illustrating a node operation waveform in the memory circuit illustrated in FIG. 13; and

FIG. 15 is a block diagram schematically illustrating a hardware configuration example of an information processing apparatus in the embodiment.

### DESCRIPTION OF EMBODIMENT(S)

Since the control signal of the pull-down circuit 63a is commonly connected to all the pull-down circuits 63a for WL signals, the driving force of the pull-down circuit control signal driver 64 that drives the pull-down circuit control signal becomes very large, increasing power consumption. In addition, since the control signal is common to all the WL signals, it operates every cycle, increasing the operating rate, and as a result, a large current flows through the power supply of the pull-down circuit control signal driver 64 at a high operating rate. Here, if the power supply wiring connected to the pull-down circuit control signal driver 64 is insufficient and the current supply is insufficient, it is impossible to maintain the potential needed for the power supply (in other words, a power drop occurs). The power drop causes problems such as malfunction and a decrease in speed.

### [A] Embodiment

Hereinafter, an embodiment will be described with reference to the drawings. However, the embodiment described below is merely an example, and there is no intention to exclude the application of various modifications and techniques that are not explicitly described in the embodiment. That is, the present embodiment can be variously modified and implemented without departing from the gist thereof. Each drawing is not intended to include only the components illustrated in the drawing, but may include other functions and the like.

Hereinafter, in the drawings, the same reference signs denote the same parts, and thus the description thereof will be omitted.

### [A-1] Example of Embodiment

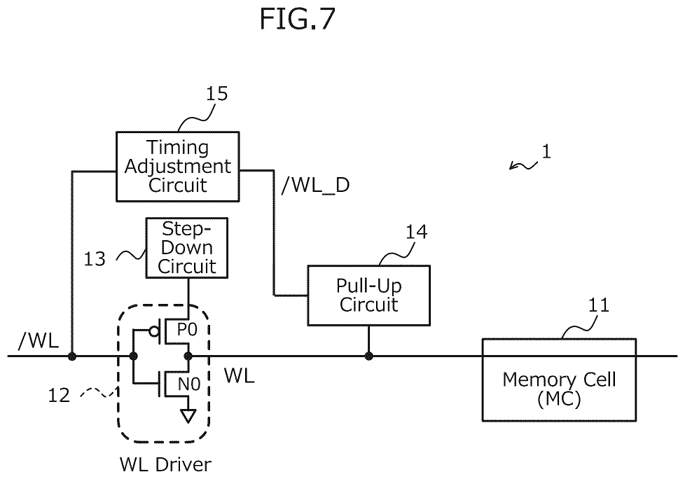

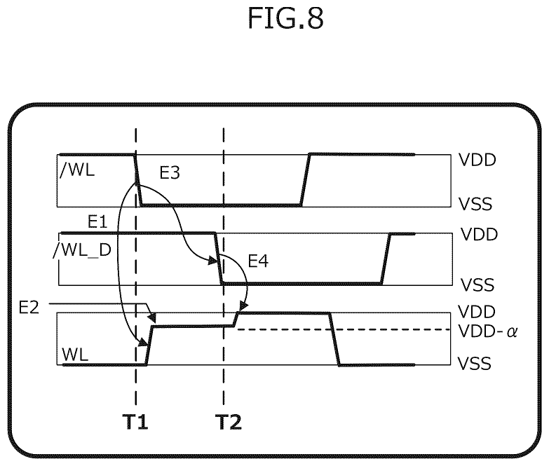

FIG. 7 is a diagram illustrating a memory circuit 1 according to the embodiment. FIG. 8 is a diagram illustrating a node operation waveform in the memory circuit 1 illustrated in FIG. 7.

As illustrated in FIG. 7, the memory circuit 1 includes an MC 11, a WL driver 12, a step-down circuit 13, a pull-up circuit 14, and a timing adjustment circuit 15.

The WL driver 12 is connected to the MC 11, and the step-down circuit 13 that suppresses a rise of the WL signal to VDD-α is connected to the WL driver 12. The word line selection signal /WL is also input to the timing adjustment circuit 15. An output /WL_D of the timing adjustment circuit 15 is connected to the pull-up circuit 14 that raises the WL signal to VDD.

As indicated by reference sign E1 in FIG. 8, /WL transitions from VDD to VSS at time T1, and the WL driver 12 causes WL to rise. Here, as indicated by reference sign E2, the step-down circuit 13 prevents the potential of the WL signal from rising to VDD, and the potential of the WL signal remains at VDD-α, which is lower by a certain amount than VDD. When the potential of WL becomes VDD-α, the MC 11 performs a read operation in a state where stability is ensured.

On the other hand, as indicated by reference sign E3, /WL is also input to the timing adjustment circuit 15, and /WL_D delayed by a time for which the stability of the MC 11 is ensured is output. /WL_D is input to the pull-up circuit 14. As indicated by reference sign E4, when the potential of /WL_D transitions from VDD to VSS, the pull-up circuit 14 raises the potential of the WL signal to the power supply voltage VDD. The rise of the potential of the WL signal to VDD improves the read speed of the MC 11.

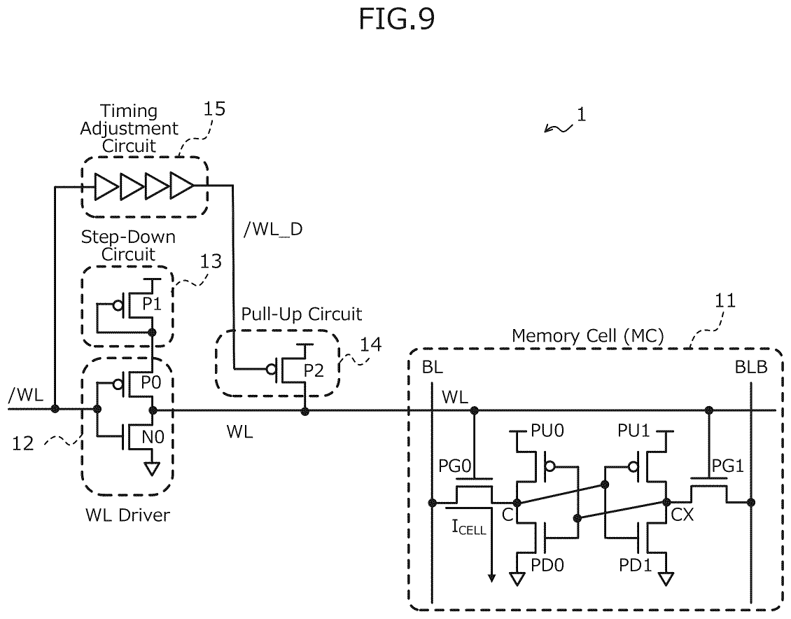

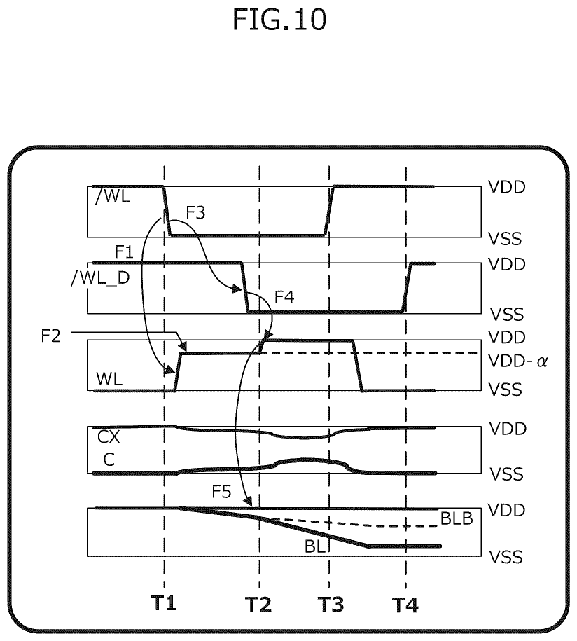

FIG. 9 is a diagram illustrating details of the memory circuit 1 illustrated in FIG. 7. FIG. 10 is a diagram illustrating a node operation waveform in the memory circuit 1 illustrated in FIG. 8.

The MC 11 includes six transistors (PU0, PU1, PG0, PG1, PD0, and PD1), and access to MC data is implemented by a WL signal.

The WL driver 12 drives the access signal WL to the MC 11. The WL driver 12 sets the potential of the WL signal input to the selected MC 11 to a second value (e.g., VDD-α), which is lower than a first value (e.g., VDD) by a certain amount, until a stable operation of the MC 11 is ensured.

The step-down circuit 13 makes the word line selection signal WL lower than the power supply voltage VDD by a certain amount.

The pull-up circuit 14 is provided between the timing adjustment circuit 15 and the signal line of the WL signal, and raises the WL signal to the power supply voltage VDD. The pull-up circuit 14 boosts the potential of the WL signal from the second value (e.g., VDD-α) to the first value (e.g., VDD) according to the time determined by the timing adjustment circuit 15.

The timing adjustment circuit 15 adjusts the operation timing of the pull-up circuit 14 from /WL. The timing adjustment circuit 15 determines a time at which the potential of the WL signal is set to the second value (e.g., VDD-α).

Here, it is assumed that the data holding node C of the MC 11 is at a low potential (LO), the data holding node CX of the MC 11 is at a high potential (HI), and the bit lines (BL and BLB) are both precharged to HI by a precharge circuit (not illustrated).

First, as indicated by reference sign F1 in FIG. 10, the /WL signal transitions from VDD to VSS at time T1.

Here, as indicated by reference sign F2, the step-down circuit 13 keeps the potential of the WL signal at VDD-α, which is lower than VDD by a certain amount. When the potential of the WL signal becomes VDD-α, the MC 11 performs a read operation in a state where stability is ensured.

After the read operation progresses and the potential of BL drops by a certain amount so that a stable operation of the MC 11 is ensured, timing (T2) delayed by a certain time by the timing adjustment circuit 15 arrives as indicated by reference sign F3.

When the input /WL_D of the pull-up circuit 14 is adjusted to LO by the timing adjustment circuit 15, the potential of the WL signal rises from VDD-α to VDD as indicated by reference sign F4.

As indicated by reference sign F5, when the potential of the WL signal rises to VDD, the driving force of PG0 of the MC 11 increases and I_{CELL} increases, improving the read speed of BL.

At this time, the time until the potential of the WL signal rises from VDD-α to VDD is determined by the delay time of the timing adjustment circuit 15. The appropriate delay time needs to be long enough to prevent data retained in C and CX from being destroyed even when a read operation is performed, assuming a case in which the stability of the MC 11 is worst. However, conversely, a shorter delay time increases the read speed.

### [A-2] First Modification

In the embodiment illustrated in FIG. 9, during a period from the time when /WL becomes HI and N0 is turned ON to the time when /WL_D becomes HI and P2 is turned OFF (between T3 and T4 in FIG. 10), a through current passing from P2 to N0 flows.

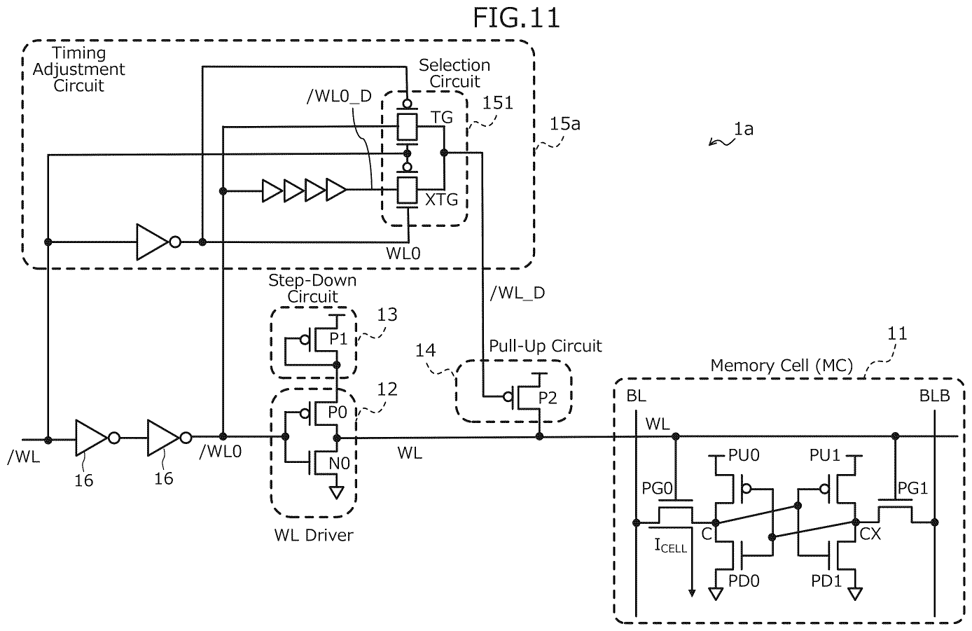

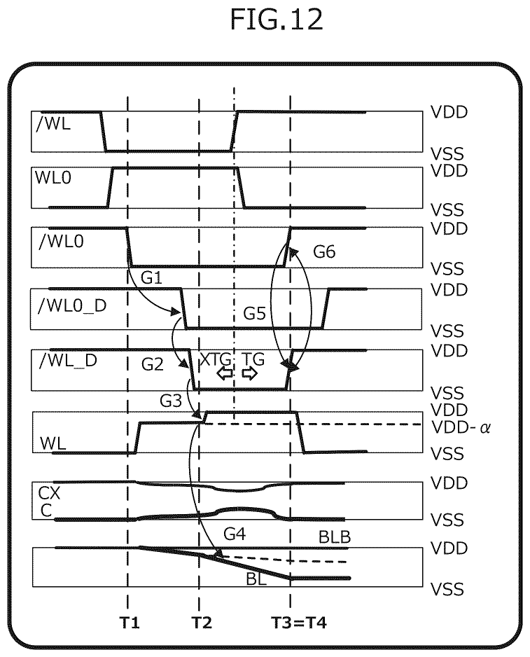

FIG. 11 is a diagram illustrating a memory circuit 1a according to a first modification. FIG. 12 is a diagram illustrating a node operation waveform in the memory circuit 1a illustrated in FIG. 11.

The memory circuit 1a illustrated in FIG. 11 has a function of suppressing a through current generated in the memory circuit 1 illustrated in FIG. 9. The memory circuit 1a includes two inverters 16 in addition to the MC 11, the WL driver 12, the step-down circuit 13, and the pull-up circuit 14 illustrated in FIG. 9. In addition, the memory circuit 1a includes a timing adjustment circuit 15a instead of the timing adjustment circuit 15 illustrated in FIG. 9.

The timing adjustment circuit 15a adjusts the operation timing of the pull-up circuit 14 from /WL0 and outputs a timing adjusted signal /WL_D. In addition, the timing adjustment circuit 15a includes a selection circuit 151 that selects either a signal /WL0_D, which is subjected to timing adjustment from /WL0, or/WL0 as it is.

The selection circuit 151 is controlled by /WL. Here, the selection circuit 151 is controlled to select /WL0_D at the timing when /WL0 transitions from VDD to VSS, and to select /WL0 at the timing when the /WL0 signal transitions from VSS to VDD. That is, the selection circuit 151 selects and outputs a signal subjected to timing adjustment or a signal not subjected to timing adjustment to adjust the time.

Here, it is assumed that the data holding node C of the MC 11 is at a low potential (LO), the data holding node CX of the MC 11 is at a high potential (HI), and the bit lines (BL and BLB) are both precharged to HI by a precharge circuit (not illustrated).

First, before time T1, the /WL signal transitions from VDD to VSS, and /WL0 transitions from VDD to VSS. Here, the step-down circuit 13 keeps the potential of the WL signal at VDD-α, which is lower than VDD by a certain amount. When the potential of the WL signal becomes VDD-α, the MC 11 performs a read operation in a state where stability is ensured.

On the other hand, /WL0 input to the timing adjustment circuit 15a at time T1 is selected by the selection circuit 151 (XTG) of the timing adjustment circuit 15a. Therefore, as indicated by reference sign G1 in FIG. 12, there is a delay until timing (T2) after the read operation progresses, and the potential of BL drops by a certain amount so that a stable operation of the MC 11 is ensured.

As indicated by reference sign G2, the /WL0_D signal propagates to the input signal /WL_D of the pull-up circuit 14 at timing (T2).

As indicated by reference sign G3, by setting /WL_D to LO, the pull-up circuit 14 is turned ON, and the potential of the WL signal rises from VDD-α to VDD.

As indicated by reference sign G4, when the potential of the WL signal rises to VDD, the driving force of PG0 of the MC 11 increases, improving the read speed. Next, at time T3, /WL0 transitions from VSS to VDD, and the WL signal transitions from VDD to VSS.

On the other hand, as indicated by reference sign G5, /WL0 input to the timing adjustment circuit 15a at time T3 causes the selection circuit 151 of the timing adjustment circuit 15a to select TG. Therefore, at time T4 with a delay corresponding to the amount of time taken for the signal to pass through the selection circuit 151 from /WL0, the signal propagates to /WL_D, causing /WL_D to become HI, thereby turning OFF the pull-up circuit 14.

As indicated by reference sign G6, by matching the timing at which N0 of the WL driver 12 is turned ON with the timing at which the pull-up circuit 14 (P2) is turned OFF (that is, T3=T4), a through current can be prevented from flowing.

### [A-3] Second Modification

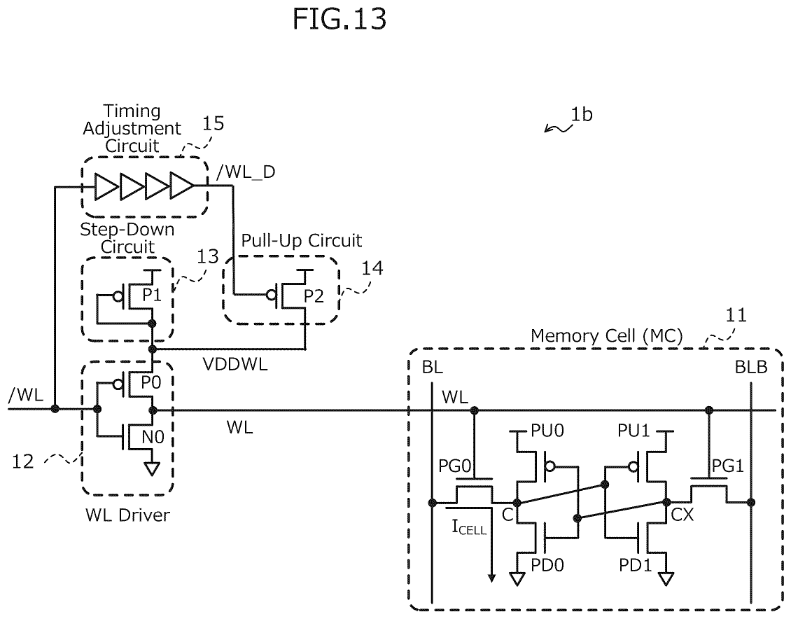

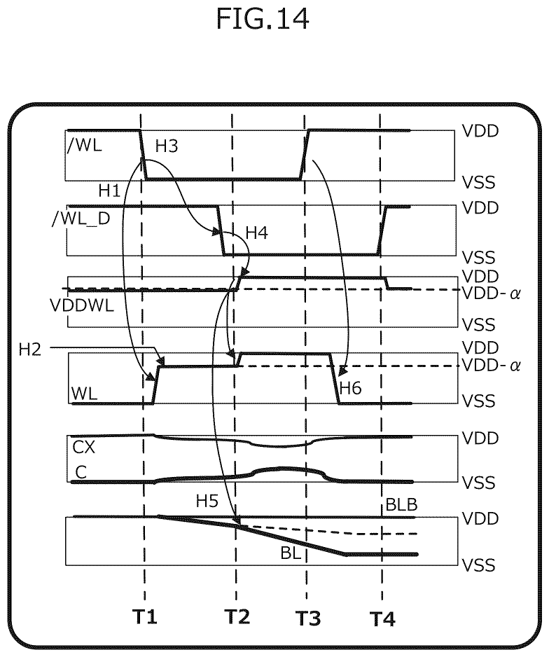

FIG. 13 is a diagram illustrating a memory circuit 1b according to a second modification. FIG. 14 is a diagram illustrating a node operation waveform in the memory circuit 1b illustrated in FIG. 13.

Similarly to the memory circuit 1a illustrated in FIG. 11, the memory circuit 1b illustrated in FIG. 13 has a function of suppressing a through current generated in the memory circuit 1 illustrated in FIG. 9. Similarly to the memory circuit 1 illustrated in FIG. 9, the memory circuit 1b illustrated in FIG. 13 includes an MC 11, a WL driver 12, a step-down circuit 13, a pull-up circuit 14, and a timing adjustment circuit 15. In FIG. 13, the pull-up circuit 14 is connected not to the WL signal but to a connection net VDDWL between the WL driver 12 and the step-down circuit 13.

It is assumed that the data holding node C of the MC 11 is at a low potential (LO), the data holding node CX of the MC 11 is at a high potential (HI), and the bit lines (BL and BLB) are both precharged to HI by a precharge circuit (not illustrated).

First, as indicated by reference sign H1 in FIG. 14, at time T1, the /WL signal transitions from VDD to VSS, and the WL driver 12 causes WL to rise.

Here, as indicated by reference sign H2, the step-down circuit 13 keeps the potential of the WL signal at VDD-α, which is lower than VDD by a certain amount. When the potential of the WL signal becomes VDD-α, the read operation is performed in the MC 11 in a state where stability is ensured.

As indicated by reference sign H3, there is a delay until timing (T2) after the read operation is progressed by the timing adjustment circuit 15, and the potential of BL drops by a certain amount so that a stable operation of the MC 11 is ensured.

As indicated by reference sign H4, at timing (T2), when the input /WL_D of the pull-up circuit 14 is adjusted to LO by the timing adjustment circuit 15, the potential of the WL signal rises from VDD-α to VDD.

As indicated by reference sign H5, when the potential of the WL signal rises to VDD, the driving force of PG0 of the MC 11 increases and I_{CELL} increases, improving the read speed.

As indicated by reference sign H6, at time T3, /WL transitions from VSS to VDD, and the WL signal transitions from VDD to VSS. At time T3, the input /WL_D of the pull-up circuit 14 is still at LO, and the pull-up circuit 14 is turned ON. However, since /WL is at HI, P0 of the WL driver 12 is turned OFF, and the through current that flows from P2 to N0, which occurs in the embodiment illustrated in FIG. 9, does not occur regardless of the timing of T4.

### [A-4] Hardware Configuration Example

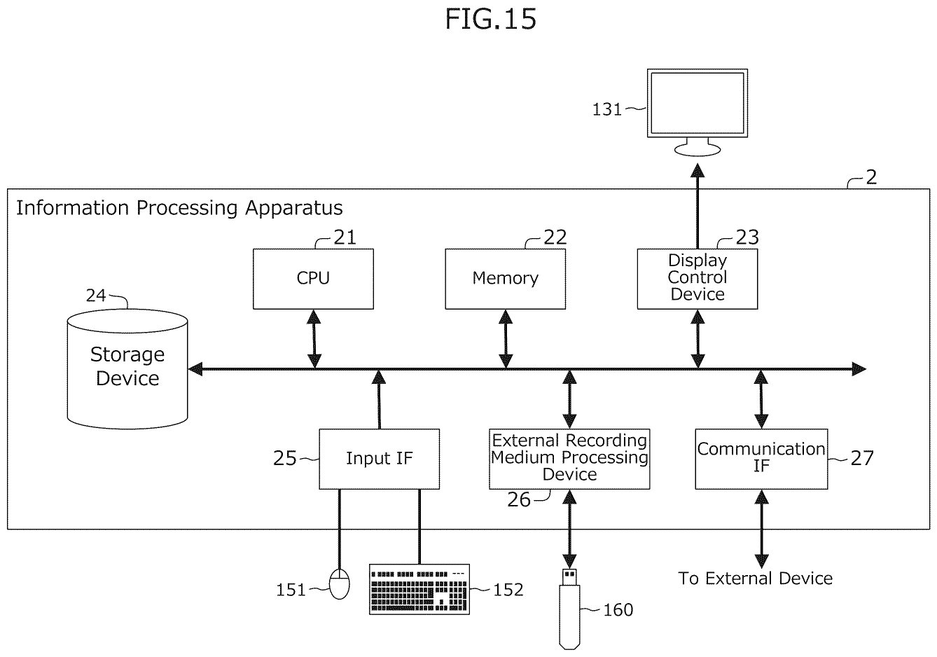

FIG. 15 is a block diagram schematically illustrating a hardware configuration example of an information processing apparatus 2 in the embodiment.

The information processing apparatus 2 may be, for example, a server, and includes a CPU 21, a memory 22, a display control device 23, a storage device 24, an input interface (IF) 25, an external recording medium processing device 26, and a communication IF 27 as illustrated in FIG. 15.

The memory 22 is an example of a storage unit, and is, for example, a read only memory (ROM) or a random access memory (RAM). A program such as a basic input/output system (BIOS) may be written in the ROM of the memory 22. The software program of the memory 22 may be appropriately read and executed by the CPU 21. In addition, the RAM of the memory 22 may be used as a temporary recording memory or a working memory. The memory 22 includes memory circuits 1, 1a, and 1b.

The display control device 23 is connected to a display device 131 and controls the display device 131. The display device 131 is a liquid crystal display, an organic light-emitting diode (OLED) display, a cathode ray tube (CRT), an electronic paper display, or the like, and displays various types of information to an operator or the like of the information processing apparatus 2. The display device 131 may be combined with an input device, and may be, for example, a touch panel. The display device 131 displays various types of information to a user of the information processing apparatus 2.

The storage device 24 is a storage device having high IO performance, and for example, a dynamic random access memory (DRAM), a solid state drive (SSD), a storage class memory (SCM), or a hard disk drive (HDD) may be used.

The input IF 25 may be connected to an input device such as a mouse 251 or a keyboard 252 and control the input device such as the mouse 251 or the keyboard 252. The mouse 251 and the keyboard 252 are examples of the input devices, and the operator performs various input operations via these input devices.

The external recording medium processing device 26 is configured so that a recording medium 160 can be mounted thereon. The external recording medium processing device 26 is configured to be able to read information recorded on the recording medium 160 in a state where the recording medium 160 is mounted thereon. In this example, the recording medium 160 has portability. For example, the recording medium 160 is a non-transitory recording medium such as a flexible disk, an optical disk, a magnetic disk, a magneto-optical disk, or a semiconductor memory.

The communication IF 27 is an interface that enables communication with an external device.

The CPU 21 is an example of a processor, and is a processing device that performs various controls and calculations. The CPU 21 implements various functions by executing an operating system (OS) and a program read into the memory 22. Note that the CPU 21 may be a multiprocessor including a plurality of CPUs or a multi-core processor including a plurality of CPU cores, or may have a configuration including a plurality of multi-core processors.

The device that controls the overall operation of the information processing apparatus 2 is not limited to the CPU 21, and may be, for example, any one of an MPU, a DSP, an ASIC, a PLD, and an FPGA. Furthermore, the device for controlling the overall operation of the information processing apparatus 2 may be a combination of two or more of the CPU, the MPU, the DSP, the ASIC, the PLD, and the FPGA. Note that the MPU is an abbreviation for micro processing unit, DSP is an abbreviation for digital signal processor, and ASIC is an abbreviation for application specific integrated circuit. In addition, PLD is an abbreviation for programmable logic device, and FPGA is an abbreviation for field programmable gate array.

### [B] Effects

According to the memory circuits 1, 1a, and 1b and the information processing apparatus 2 in the above-described embodiment, for example, the following operational effects can be achieved.

The WL driver 12 sets a potential of a WL signal input to a selected MC 11 to a second value lower than a first value by a certain amount until a stable operation of the MC 11 is ensured. The timing adjustment circuit 15 determines a time at which the potential of the WL signal is set to the second value. The pull-up circuit 14 boosts the potential of the WL signal from the second value to the first value according to the determined time.

This eliminates the need for a pull-down circuit control signal driver having a large driving force and a high operation rate for controlling a large number of WL pull-down circuits as in the conventional technology. Instead, the added timing adjustment circuit 15 needs to be added for each WL, but only the pull-up circuit 14 for each WL signal needs to be controlled, and therefore the driving force is very small. In addition, only the timing adjustment circuit 15 corresponding to the WL that needs to be operated operates and the others do not operate, making it possible to realize a read assist of the same WL underdrive method with power saving and low power drop as compared with the conventional technology.

The pull-up circuit 14 is provided between the timing adjustment circuit 15 and a signal line for the WL signal.

This can boost the potential of the WL signal after the determined time elapses.

The timing adjustment circuit 15 includes a selection circuit 151 that selects and outputs a signal subjected to timing adjustment or a signal not subjected to timing adjustment to adjust the time.

This can prevent a through current flowing from the pull-up circuit 14 to the WL driver 12.

The step-down circuit 13 steps down the potential of the WL signal from the first value to the second value. The pull-up circuit 14 is connected to the timing adjustment circuit 15, and is connected between the WL driver 12 and the step-down circuit 13.

Thus, the timing adjustment circuit 15 having a simple configuration can prevent a through current flowing from the pull-up circuit 14 to the WL driver 12.

### [C] Others

The disclosed technology is not limited to the above-described embodiment, and various modifications can be made without departing from the gist of the present embodiment. Each configuration and each process of the present embodiment can be selected or omitted as needed or may be appropriately combined.

In one aspect, it is possible to realize a read assist using the word line underdrive method with power saving and low power drop.

Throughout the descriptions, the indefinite article “a” or “an” does not exclude a plurality.

All examples and conditional language recited herein are intended for the pedagogical purposes of aiding the reader in understanding the invention and the concepts contributed by the inventor to further the art, and are not to be construed limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. A memory circuit comprising:
a word line driver configured to set a potential of a word line signal input to a selected memory cell to a second value lower than a first value by a certain amount until a stable operation of the memory cell is ensured;
a timing adjustment circuit configured to determine a time at which the potential of the word line signal is set to the second value; and
a pull-up circuit configured to boost the potential of the word line signal from the second value to the first value according to the determined time.

2. The memory circuit according to claim 1, wherein
the pull-up circuit is provided between the timing adjustment circuit and a signal line for the word line signal.

3. The memory circuit according to claim 1, wherein
the timing adjustment circuit includes a selection circuit configured to select and output a signal subjected to timing adjustment or a signal not subjected to timing adjustment to adjust the time.

4. The memory circuit according to claim 2, wherein
the timing adjustment circuit includes a selection circuit configured to select and output a signal subjected to timing adjustment or a signal not subjected to timing adjustment to adjust the time.

5. The memory circuit according to claim 1, further comprising:
a step-down circuit configured to step down the potential of the word line signal from the first value to the second value,
wherein the pull-up circuit is connected to the timing adjustment circuit, and is connected between the word line driver and the step-down circuit.

6. An information processing apparatus comprising a processor and a memory having a memory circuit,
wherein the memory circuit includes:
a word line driver configured to set a potential of a word line signal input to a selected memory cell to a second value lower than a first value by a certain amount until a stable operation of the memory cell is ensured;
a timing adjustment circuit configured to determine a time at which the potential of the word line signal is set to the second value; and
a pull-up circuit configured to boost the potential of the word line signal from the second value to the first value according to the determined time.

7. The information processing apparatus according to claim 6, wherein
the pull-up circuit is provided between the timing adjustment circuit and a signal line for the word line signal.

8. The information processing apparatus according to claim 6, wherein
the timing adjustment circuit includes a selection circuit configured to select and output a signal subjected to timing adjustment or a signal not subjected to timing adjustment to adjust the time.

9. The information processing apparatus according to claim 7, wherein
the timing adjustment circuit includes a selection circuit configured to select and output a signal subjected to timing adjustment or a signal not subjected to timing adjustment to adjust the time.

10. The information processing apparatus according to claim 6, further comprising:
a step-down circuit configured to step down the potential of the word line signal from the first value to the second value,
wherein the pull-up circuit is connected to the timing adjustment circuit, and is connected between the word line driver and the step-down circuit.
